(19) United States
(12) Patent Application Publication
(10) Pub. No.: US 2026/0344131 A1
(43) Pub. Date: Oct. 29, 2026

(54) DISPLAY DEVICE

(71) Applicant: LG ELECTRONICS INC., Seoul (KR)

(72) Inventors: Seungmi BAEK, Seoul (KR); Younggil YOO, Seoul (KR)

(73) Assignee: LG ELECTRONICS INC., Seoul (KR)

(21) Appl. No.: 19/109,092

(22) PCT Filed: Sep. 7, 2022
(86) PCT No.: PCT/KR2022/013433

§ 371 Date: Mar. 5, 2025

(51) Int. Cl. H10H 20/855; H10H 20/01; H10H 20/851

(52) U.S. Cl. CPC H10H 20/855; H10H 20/0361; H10H 20/0363; H10H 20/8512

(57) ABSTRACT

The display device may include a substrate, a plurality of semiconductor light-emitting elements on the substrate, a refractive index layer on the plurality of semiconductor light-emitting elements, and a color conversion layer on the refractive index layer. The color conversion layer may include color conversion particles. Some of the color conversion particles are disposed in the refractive index layer.

### TECHNICAL FIELD

The embodiment relates to a display device.

### BACKGROUND ART

A display devices are being adopted in various fields. In particular, not only TV display field but also augmented reality (AR)-based display field and head-up display (HUD) field for an automobile have been receiving much attention recently.

The AR or HUD display device requires ultra-high resolution. To this end, the display device that displays images using high-luminance and small-sized light-emitting diodes as light sources for pixels is in the spotlight.

FIG. 1 is a cross-sectional view illustrating a typical display device.

As illustrated in FIG. 1, a plurality of semiconductor light-emitting elements 1 to 3 that generate the same color light 6 are provided for subpixels PX1 to PX3, respectively, and color conversion layers 4 and 5 are provided for some pixels PX1 and PX2.

For example, in the first subpixel PX1, blue light 6 generated from the semiconductor light-emitting element 1 is converted into red light by the color conversion layer 4. For example, in the second subpixel PX2, blue light 6 generated from the semiconductor light-emitting element 2 is converted into green light by the color conversion layer 5. For example, in the third subpixel PX3, blue light 6 generated from the semiconductor light-emitting element 3 is transmitted forward as is.

However, in the display device illustrated in FIG. 1, since the color conversion efficiency in the color conversion layers 4 and 5 is not good, it is difficult to secure the target luminance of each of the red light 7 and the green light 8, and it is also difficult to maintain the luminance balance between the subpixels PX1 to PX3.

In addition, since the blue light 6 generated from the semiconductor light-emitting elements 1 and 2 are directly incident on the color conversion layers 4 and 5, and the refractive index difference between the semiconductor light-emitting elements 1 and 2 and the color conversion layers 4 and 5 are large, there is a problem that the total internal reflection area is large so the luminance is reduced.

### DISCLOSURE

### Technical Problem

An object of the embodiment is to solve the foregoing and other problems.

Another object of the embodiment is to provide a display device capable of securing a target luminance.

In addition, another object of the embodiment is to provide a display device capable of maintaining luminance balance.

In addition, another object of the embodiment is to provide a display device capable of improving luminance.

The technical problems of the embodiments are not limited to those described in this item and comprise those that may be understood through the description of the invention.

### Technical Solution

In order to achieve the above or other objects, according to one aspect of the embodiment, a display device, comprising: a substrate; a plurality of semiconductor light-emitting elements on the substrate; a refractive index layer on the plurality of semiconductor light-emitting elements; and a color conversion layer on the refractive index layer, wherein the color conversion layer comprises color conversion particles, and wherein some of the color conversion particles are disposed in the refractive index layer.

The refractive index layer may comprise a plurality of pore passages; and some of the color conversion particles may be disposed in the plurality of pore passages.

Some of the color conversion particles may be spaced from the plurality of semiconductor light-emitting elements.

The refractive index layer may comprise: a first refractive index region adjacent to the plurality of semiconductor light-emitting elements; and a second refractive index region on the first refractive index region. Some of the color conversion particles may be disposed in the pore passages of the second refractive index region.

The display device may comprise air in the pore passages of the first refractive index region.

The refractive index layer may comprise a member, and the plurality of pore passages may be disposed in the member.

The member may comprise an organometallic compound, a metal oxide, deionized water, and an additive.

Some among the plurality of pore passages may be in contact with the plurality of semiconductor light-emitting elements through a lower surface of the member or be in contact with the color conversion layer through an upper surface of the member.

The color conversion particles of the color conversion layer and the color conversion particles of the plurality of pore passages may be in contact with each other on the upper surface of the member.

The plurality of pore passages may be three-dimensionally curved.

The plurality of pore passages may be disposed along at least two directions among a X-axis direction, a Y-axis, a Z-axis direction, a diagonal direction, a gravity direction, a direction against gravity, a horizontal direction, a clockwise direction, or a counterclockwise direction.

Each of the plurality of pore passages may have a width that is at least twice or more a size of the color conversion particle.

The substrate may comprise a first subpixel, a second subpixel, and a third subpixel. The plurality of semiconductor light-emitting elements may comprise: at least one or more first semiconductor light-emitting element in the first subpixel; at least one or more second semiconductor light-emitting element in the second subpixel; and at least one or more third semiconductor light-emitting element in the third subpixel. The first semiconductor light-emitting element, the second semiconductor light-emitting element and the third semiconductor light-emitting element may generate first color light.

The refractive index layer may comprise: a first refractive index layer on the at least one or more first semiconductor light-emitting element; a second refractive index layer on the at least one or more second semiconductor light-emitting element; and a third refractive index layer on the at least one or more third semiconductor light-emitting element. A refractive index of each of the first refractive index layer, the second refractive index layer, and the third refractive index layer may be smaller than a refractive index of the first semiconductor light-emitting element.

The color conversion layer may comprise: a first color conversion layer comprising first color conversion particles that convert the first color light into second color light on the first refractive index layer; and a second color conversion layer comprising second color conversion particles that convert the first color light into third color light on the second refractive index layer.

Some of the first color conversion particles may be disposed in the first refractive index layer, and some of the second color conversion particles may be disposed in the second refractive index layer.

The first refractive index layer may comprise a plurality of first pore passages, the second refractive index layer may comprise a plurality of second pore passages, and the third refractive index layer may comprise a plurality of third pore passages. Some of the first color conversion particles may be disposed in the plurality of first pore passages, and some of the second color conversion particles may be disposed in the plurality of second pore passages.

The display device may comprise: a light-transmitting layer configured to transmit the first color light on the third refractive index layer.

The display device may comprise: a bank between the first refractive index layer, the second refractive index layer, and the third refractive index layer.

The color conversion layer may have a thickness that is 1/10 or less of a thickness of the refractive index layer.

### Advantageous Effects

As illustrated in FIGS. 2 to 4 and FIG. 8, a plurality of semiconductor light-emitting elements 121 to 123 that emit the same color light, i.e., first color light 161, may be disposed in a first subpixel PX1, a second subpixel PX2, and a third subpixel PX3.

A second color light may be output from the first subpixel PX1, a third color light may be output from the second subpixel PX2, and the first color light 161 may be output from the third subpixel PX3. To this end, a first color conversion layer 141 that converts the first color light 161 into the second color light may be disposed in the first subpixel PX1, and a second color conversion layer 142 that converts the first color light 161 into the third color light may be disposed in the second subpixel PX2. The first color conversion layer 141 may comprise a first color conversion particles 141a, and the second color conversion layer 142 may comprise a second color conversion particles 142a.

Meanwhile, a refractive index layer 130 may be disposed between the plurality of semiconductor light-emitting elements 121 to 123 and a color conversion layer 140. The refractive index layer 130 may comprise a first refractive index layer 131 disposed in the first subpixel PX1, a second refractive index layer 132 disposed in the second subpixel PX2, and a third refractive index layer 133 disposed in the third subpixel PX3.

In an embodiment, a refractive index of the refractive index layer 130 may be smaller than a refractive index of the semiconductor light-emitting element and greater than a refractive index of the atmospheric layer (190 of FIG. 9). Therefore, total internal reflection in the refractive index layer 130 can be minimized, light extraction efficiency can be maximized, and luminance can be improved. For example, the first refractive index layer 131, the second refractive index layer 132, and the third refractive index layer 133 may have the same refractive index, but is not limited thereto.

For example, since total internal reflection is minimized in the first refractive index layer 131, first color light 161 of the first semiconductor light-emitting element 121 may be more incident on the first refractive index layer 131, so that luminance can be improved. For example, since total internal reflection is minimized in the second refractive index layer 132, first color light 161 of the second semiconductor light-emitting element 122 may be more incident on the second refractive index layer 132, so that luminance can be improved. For example, since total internal reflection is minimized in the third refractive index layer 133, first color light 161 of the third semiconductor light-emitting element 123 may be more incident on the third refractive index layer 133, so that luminance can be improved.

In an embodiment, the refractive index layer 130 may comprise a plurality of pore passages 131-2 and 133-2. Accordingly, the first color light 161 of the semiconductor light-emitting element may be refracted or diffusely reflected by the plurality of pore passages 131-2 and 133-2, so that the first color light 161 may travel to the entire region of the refractive index layer 130 without passing directly through the refractive index layer 130.

As will be described later, the refractive index layer 130 may also perform color conversion. The longer the first color light 161 may stay in the refractive index layer 130, the more the color conversion efficiency of converting the first color light 161 into the second color light or the third color light can be improved.

For example, the first refractive index layer 131 may comprise a plurality of first pore passages 131-2, the second refractive index layer 132 may comprise a plurality of second pore passages 132-2, and the third refractive index layer 133 may comprise a plurality of third pore passages 133-2.

For example, the first refractive index layer 131 may comprise first color conversion particles 141b, and the second refractive index layer 132 may comprise second color conversion particles 142b. The first color light 161 may be converted into the second color light by the first color conversion particles 141b, and the first color light 161 may be converted into the third color light by the second color conversion particles 142b.

Specifically, the first color conversion particles 141b may be disposed in the plurality of first pore passages 131-2 of the first refractive index layer 131, and the second color conversion particles 142b may be disposed in the plurality of second pore passages 132-2 of the second refractive index layer 132.

The first color light 161 may be refracted or diffusely reflected by the plurality of first pore passages 131-2, so that the first color light 161 may travel throughout the entire region of the first refractive index layer 131 and stay in the first refractive index layer 131 for a longer time. Thus, the probability that the first color light 161 may be converted into second color light by the plurality of first color conversion particles 141b disposed in the plurality of first pore passages 131-2 may increase further, so that the color conversion efficiency can be improved. Since the color conversion efficiency is improved, the luminance can be improved. Likewise, the first color light 161 may be refracted or diffusely reflected by the plurality of second pore passages 132-2, so that the first color light 161 may travel to the entire region of the second refractive index layer 132 and stay in the second refractive index layer 132 for a longer time. Thus, the probability that the first color light 161 may be converted into the third color light by the plurality of second color conversion particles 142b disposed in the plurality of second pore passages 132-2 may increase further, so that the color conversion efficiency can be improved. Since the color conversion efficiency is improved, the luminance can be improved.

According to an embodiment, since color conversion is performed not only in the color conversion layer 140 but also in the refractive index layer 130, the color conversion efficiency can be significantly improved. In particular, the first color light 161 of the semiconductor light-emitting element does not pass directly through the refractive index layer 130 but propagates through the entire region of the first refractive index layer 131 by the plurality of pore passages 131-2 and 133-2 included in the refractive index layer 130, so that the color conversion efficiency in which the first color light or the third color light is converted by the first color conversion particles 141b or the second color conversion particles 142b can be significantly improved.

According to an embodiment, the first color conversion particles or the second color conversion particles may be mainly disposed in the plurality of pore passages 131-2 and 133-2 of the refractive index layer 130, and only some of them may be included in the color conversion layer 140 on the refractive index layer 130. Normally, in a color conversion layer disposed on a plane, the first color conversion particles or the second color conversion particles is likely to clump together. In the embodiment, the thickness W2 of the color conversion layer 140 may be set to 1/10 or less of the thickness W1 of the refractive index layer 130, so that the first color conversion particles 141a or the second color conversion particles 142a do not clump together. Since the plurality of pore passages 131-2 and 133-2 included in the refractive index layer 130 have a three-dimensionally curved shape, the first color conversion particles 141b or the second color conversion particles 142b do not clump together within the plurality of pore passages 131-2 and 133-2 having the three-dimensionally curved shape. Accordingly, since the first color conversion particles 141a and 141b or the second color conversion particles 142b have excellent quality without defects in the refractive index layer 130 or the color conversion layer 140, the color conversion efficiency can be maximized.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 is a cross-sectional view illustrating a typical display device.

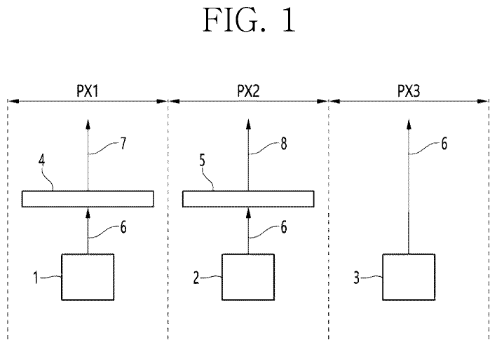

FIG. 2 is a cross-sectional view illustrating a display device according to an embodiment.

FIG. 3 is a first cross-sectional view illustrating PX1 of FIG. 2 in detail.

FIG. 4 is a first cross-sectional view illustrating PX2 of FIG. 2 in detail.

FIG. 5 is a second cross-sectional view illustrating PX1 of FIG. 2 in detail.

FIG. 6 is a second cross-sectional view illustrating PX2 of FIG. 2 in detail.

FIG. 7 illustrates a state in which the first color conversion particles are disposed in the first pore passage.

FIG. 8 illustrates a state in which a first color light, a second color light, and a third color light propagation in a display device according to an embodiment.

FIG. 9 illustrates a state in which each color light propagationes between a first semiconductor light-emitting element, a first refractive index layer, and an atmospheric layer.

FIG. 10A illustrates a state in which color light propagationes when there is no first refractive index layer.

FIG. 10B illustrates a state in which color light propagationes when the first refractive index layer is provided.

FIGS. 11A to 11F illustrate a manufacturing process of a display device according to an embodiment.

FIG. 12 illustrates a state in which pore passages are formed.

FIGS. 13A and 13B illustrate a state in which a semiconductor light-emitting element is assembled using a self-assembly process.

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

The display device described in this specification may comprise a TV, a signage, a mobile phone, a smart phone, a head-up display (HUD) for an automobile, a backlight unit for a laptop computer, a display for VR, AR or mixed reality (MR), etc. However, the configuration according to the embodiment described in this specification may also be applied to a device capable of displaying, even if it is a new product type developed in the future.

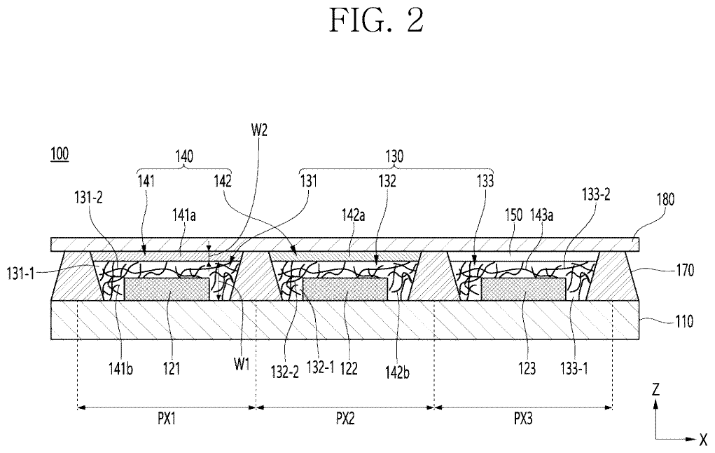

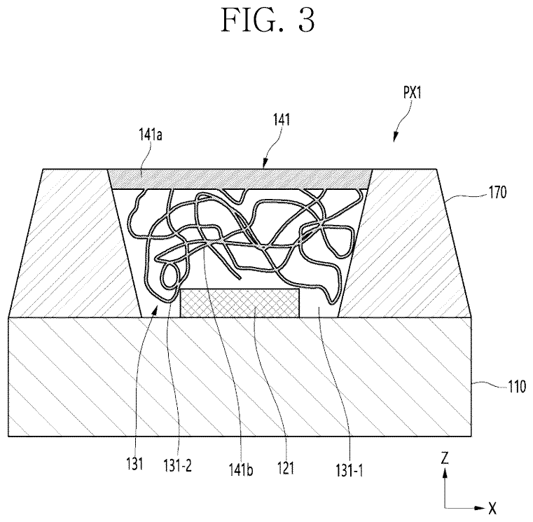

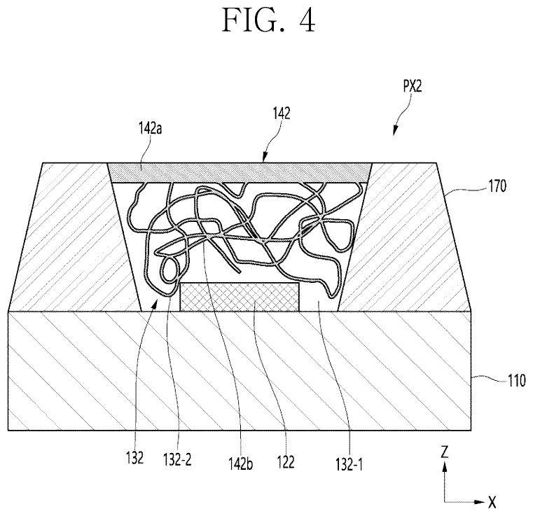

FIG. 2 is a cross-sectional view illustrating a display device according to an embodiment. FIG. 3 is a first cross-sectional view illustrating PX1 of FIG. 2 in detail. FIG. 4 is a first cross-sectional view illustrating PX2 of FIG. 2 in detail.

Referring to FIGS. 2 to 4, the display device 100 according to an embodiment may comprise a substrate 110, a plurality of semiconductor light-emitting elements 121 to 123, a refractive index layer 130, and a color conversion layer 140. The display device 100 according to an embodiment may comprise more components than these, but is not limited thereto.

The substrate 110 may be a support member for supporting the plurality of semiconductor light-emitting elements, the refractive index layer 130, and the color conversion layer 140. The substrate 110 may be a rigid substrate, a flexible substrate, a rollable substrate, etc. The substrate 110 may be made of a transparent material or an opaque material. As an example, in a top emission display device in which light propagates forward to implement an image, the substrate 110 may be made of an opaque material. When the substrate 110 in the top-emitting display device is made of a transparent material, a reflector may be disposed between the substrate 110 and the plurality of semiconductor light-emitting elements, so that the light of the plurality of semiconductor light-emitting elements may be reflected forward rather than propagating downward through the substrate 110 by the reflector.

A plurality of semiconductor light-emitting elements may be disposed on the substrate 110. The plurality of semiconductor light-emitting elements may emit the same color light, for example, the first color light, but is not limited thereto.

A refractive index layer 130 may be disposed on the plurality of semiconductor light-emitting elements. The refractive index layer 130 may enable the first color light emitted from the plurality of semiconductor light-emitting elements to be emitted to a wider light source. That is, the refractive index layer 130 may adjust the refractive index between the refractive index of the plurality of semiconductor light-emitting elements and the refractive index of the air in the external, i.e., the atmospheric layer, to reduce a total internal reflection area of the first color light of the plurality of semiconductor light-emitting elements, so that a first color light can be more emitted, thereby increasing light efficiency and improving luminance. The first color light of the plurality of semiconductor light-emitting elements may be emitted more widely, so that color conversion may be performed in a wider region in the color conversion layer 140, thereby improving the color conversion efficiency and further improving the luminance.

The color conversion layer 140 may be disposed on the refractive index layer 130. The color conversion layer 140 may convert the first color light of the plurality of semiconductor light-emitting elements into the second color light or the third color light, or may emit the light as is without conversion.

As an example, the first color light may comprise blue light or purple light, the second color light may comprise red light, and the third color light may comprise green light.

As another example, the first color light may comprise white light, the second color light may comprise red light, and the third color light may comprise green light. When the first color light is white light, the second color light may be a color light other than red light, and the third color light may be a color light other than green light, but is not limited thereto.

Hereinafter, the refractive index layer 130 and the color conversion layer 140 will be described in more detail.

A plurality of pixels may be implemented on the substrate 110. The plurality of pixels may comprise a plurality of subpixels PX1, PX2, and PX3 for displaying a full-color image, respectively. For example, a second color light may be emitted from a first subpixel PX1, a third color light may be emitted from a second subpixel PX2, and a first color light may be emitted from a third subpixel PX3, so that a full-color image may be displayed by the second color light, the third color light, and the first color light.

The plurality of semiconductor light-emitting elements may emit the same color light, that is, the first color light.

In an embodiment, the plurality of semiconductor light-emitting elements may each be a semiconductor light-emitting element having a size of micrometers or less.

The first color light emitted from each of the plurality of semiconductor light-emitting elements may be converted into a second color light or a third color light by passing through the refractive index layer 130 and the color conversion layer 140, or may be emitted as the first color light.

The plurality of semiconductor light-emitting elements may comprise at least one or more first semiconductor light-emitting element 121 in the first subpixel PX1, at least one or more second semiconductor light-emitting element 122 in the second subpixel PX2, and at least one or more third semiconductor light-emitting element 123 in the third subpixel PX3.

The refractive index layer 130 may be disposed on the plurality of semiconductor light-emitting elements. The refractive index layer 130 may be disposed in the first subpixel PX1, the second subpixel PX2, and the third subpixel PX3. For example, a refractive index of the refractive index layer 130 may be smaller than a refractive index of each of the plurality of semiconductor light-emitting elements and greater than a refractive index of air in the external, i.e., atmospheric layer. The refractive index of the refractive index layer 130 may be, for example, 1.7 to 2.2, but is not limited thereto.

According to an embodiment, the refractive index layer 130 may comprise color conversion particles disposed in the plurality of pore passages 131-2 and 133-2. The color conversion particles may convert color of the first color light emitted from the plurality of semiconductor light-emitting elements. The color conversion particles may be, for example, quantum dots and may be made of a semiconductor material. Depending on the size or shape of the color conversion particles, the first color light may be converted into the second color light or the third color light.

As will be described later, the first color conversion particles 141b may be disposed in the refractive index layer 130 corresponding to the first subpixel PX1, i.e., the first refractive index layer 131, and the first color light of the first semiconductor light-emitting element 121 may be converted into the second color light by the first color conversion particles 141b. The second color conversion particles 142b may be disposed on a refractive index layer 130 corresponding to the second subpixel PX2, that is, the second refractive index layer 132, and the first color light of the second semiconductor light-emitting element 122 may be converted into a third color light by the second color conversion particles 142b.

The refractive index layer 130 may comprise a first refractive index layer 131 disposed in the first subpixel PX1, a second refractive index layer 132 disposed in the second subpixel PX2, and a third refractive index layer 133 disposed in the third subpixel PX3. The first refractive index layer 131 may be disposed on at least one or more first semiconductor light-emitting element 121 in the first subpixel PX1. The second refractive index layer 132 may be disposed on at least one or more second semiconductor light-emitting element 122 in the second subpixel PX2. The third refractive index layer 133 may be disposed on at least one or more third semiconductor light-emitting element 123 in the third subpixel PX3. The refractive index of the first refractive index layer 131 may be smaller than the refractive index of the first semiconductor light-emitting element 121, the refractive index of the second refractive index layer 132 may be smaller than the refractive index of the second semiconductor light-emitting element 122, and the refractive index of the third refractive index layer 133 may be smaller than the refractive index of the third semiconductor light-emitting element 123.

For example, the first refractive index layer 131 may comprise a plurality of first pore passages 131-2, the second refractive index layer 132 may comprise a plurality of second pore passages 132-2, and the third refractive index layer 133 may comprise a plurality of third pore passages 133-2. In this instance, the first color conversion particles 141b may be disposed in the plurality of first pore passages 131-2 of the first refractive index layer 131, so that the first color light of the first semiconductor light-emitting element 121 may be converted into the second color light. The second color conversion particles 142b may be disposed in the plurality of second pore passages 132-2 of the second refractive index layer 132, so that the first color light of the second semiconductor light-emitting element 122 may be converted into the third color light.

Meanwhile, since no color conversion particles are disposed in the plurality of third pore passages 133-2 of the third refractive index layer 133, the first color light of the third semiconductor light-emitting element 123 may be emitted as is without conversion. The plurality of third pore passages 133-2 may be filled with air 143a. Accordingly, the first color light of the third semiconductor light-emitting element 123 may be incident on the third refractive index layer 133, and may be scattered or refracted by the air 143a of the plurality of third pore passages 133-2, so that the first color light may be emitted with an even wider radiation angle.

Meanwhile, the refractive index layer 130 may comprise members 131-1 to 133-1, and a plurality of pore passages may be disposed in the members 131-1 to 133-1. That is, the first refractive index layer 131, the second refractive index layer 132, and the third refractive index layer 133 each comprise members 131-1 to 133-1, and a plurality of first pore passages 131-2, a plurality of second pore passages 132-2, and a plurality of third pore passages 133-2 may be disposed in the members 131-1 to 133-1.

For example, a first refractive index layer 131 may comprise a first member 131-1, a plurality of first pore passages 131-2, and first color conversion particles 141b. The plurality of first pore passages 131-2 may be disposed in the first member 131-1, and the first color conversion particles 141b may be disposed in the plurality of first pore passages 131-2. For example, a second refractive index layer 132 may comprise a second member 132-1, a plurality of second pore passages 132-2, and second color conversion particles 142b. The plurality of second pore passages 132-2 may be disposed in the second member 132-1, and the second color conversion particles 142b may be disposed in the plurality of second pore passages 132-2. For example, a third refractive index layer 133 may comprise a third member 133-1, a plurality of third pore passages 133-2, and a third color conversion particle. The plurality of third pore passages 133-2 may be disposed in the third member 133-1, and the third color conversion particles may be disposed in the plurality of third pore passages 133-2.

The first member 131-1, the second member 132-1, and the third member 133-1 may be made of the same material, but are not limited thereto. For example, the first member 131-1, the second member 132-1, and the third member 133-1 may each comprise an organometallic compound, a metal oxide, deionized water, an additive, etc. The metal oxide may be, for example, nano TiO₂, but is not limited thereto. The organometallic compound may be, for example, a titanium (IV) isopropoxide system, but is not limited thereto.

Meanwhile, the plurality of pore passages 131-2 and 133-2 may have a three-dimensionally curved shape. For example, the plurality of pore passages 131-2 and 133-2 may be disposed along at least two or more directions among a X-axis direction, a Y-axis direction, a Z-axis direction, a diagonal direction, a gravity direction, a direction against gravity, a horizontal direction, a clockwise direction, or a counterclockwise direction. The plurality of pore passages 131-2 and 133-2 may be connected to each other. For example, each of the plurality of pore passages 131-2 and 133-2 may be disposed along at least two or more directions among the X-axis direction, the Y-axis and the Z-axis direction, the diagonal direction, the gravity direction, the direction against gravity, the horizontal direction, the clockwise direction, or the counterclockwise direction, and may be connected to each other. Some of the plurality of pore passages 131-2 and 133-2 may not be connected to each other and may be isolated.

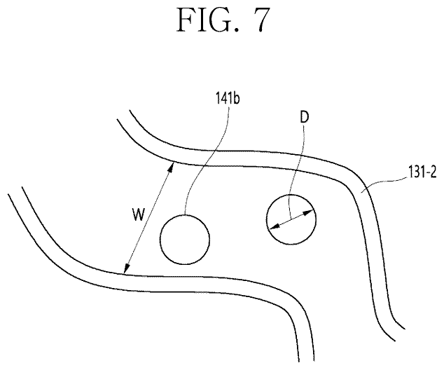

The first color conversion particles 141b may be disposed in the plurality of first pore passages 131-2. As illustrated in FIG. 7, the first pore passage 131-2 may have a width W that is at least twice or more a size D of the first color conversion particle 141b. The first color conversion particles 141b may or may not be in contact with each other in each of the plurality of first pore passages 131-2. For example, some of the first color conversion particles 141b may be in contact with each other and others may not be in contact with each other.

The second color conversion particles 142b may be disposed in the plurality of second pore passages 132-2. Although not illustrated, the second pore passages 132-2 may have a width that is at least twice or more a size of the second color conversion particle 142b. The second color conversion particles 142b may or may not contact each other in each of the plurality of second pore passages 132-2. For example, some of the second color conversion particles 142b may be in contact with each other and others may not contact each other.

Meanwhile, some of the pore passages 131-2 and 133-2 may be in contact with the plurality of semiconductor light-emitting elements through the lower surfaces of the members 131-1 to 133-1, but is not limited thereto.

According to an embodiment, the first color light of the plurality of semiconductor light-emitting elements may be incident on the refractive index layer 130, and color conversion may be performed while passing through the refractive index layer 130, so that the second color light or the third color light may be emitted, and also the total internal reflection area can be reduced to increase the light extraction efficiency, thereby improving the luminance.

Meanwhile, the color conversion layer 140 may be disposed on the refractive index layer 130. The color conversion layer 140 may comprise color conversion particles.

The color conversion layer 140 may perform color conversion so that the first subpixel PX1 may emit a second color light, the second subpixel PX2 may emit a third color light, and the third subpixel PX3 may emit a first color light. That is, the second color light may be emitted using the first color light of the first semiconductor light-emitting element 121 in the first subpixel PX1, the third color light may be emitted using the first color light of the second semiconductor light-emitting element 122 in the second subpixel PX2, and the first color light of the third semiconductor light-emitting element 123 in the third subpixel PX3 may be emitted as is.

For example, the color conversion layer 140 may comprise the first color conversion layer 141 in the first subpixel PX1 and the second color conversion layer 142 in the second subpixel PX2.

The first color conversion layer 141 may be disposed on the first refractive index layer 131 in the first subpixel PX1. The first color conversion layer 141 may comprise first color conversion particles 141a. The first color conversion particles 141a may convert the first color light of the first semiconductor light-emitting element 121 into second color light.

A lower surface of the first color conversion layer 141 may be in contact with an upper surface of the first refractive index layer 131. The plurality of first pore passages 131-2 of the first refractive index layer 131 may be in contact with the lower surface of the first color conversion layer 141.

The first color conversion particles 141a may be included in the first color conversion layer 141, and the first color conversion particles 141b may be disposed in the plurality of first pore passages 131-2 of the first refractive index layer 131. In this instance, the first color conversion particles 141a of the first color conversion layer 141 and the first color conversion particles 141b disposed in the plurality of first pore passages 131-2 of the first refractive index layer 131 may be in contact with each other on the upper surface of the first member 131-1.

As will be described later, a first color conversion solution comprising the plurality of first color conversion particles 141a and 141b may be applied and cured on the first refractive index layer 131. Here, curing may mean thermal curing, but is not limited thereto. Accordingly, some of the plurality of first color conversion particles 141a and 141b may be injected into and fixed through the plurality of pore passages 131-2 and 133-2 of the first refractive index layer 131, thereby remaining as first color conversion particles 141b. The remaining particles among the plurality of first color conversion particles 141a and 141b that are not injected into the plurality of first pore passages 131-2 of the first refractive index layer 131, i.e., the first color conversion particles 141a, may form the first color conversion layer 141 on the first refractive index layer 131.

The first color conversion solution may be formed by mixing a resin, a plurality of first color conversion particles 141a and 141b, an additive, etc.

The second color conversion layer 142 may be disposed on the second refractive index layer 132 in the second subpixel PX2. The second color conversion layer 142 may comprise second color conversion particles 142a. The second color conversion particles 142a may convert the first color light of the second semiconductor light-emitting element 122 into third color light.

A lower surface of the second color conversion layer 142 may be in contact with an upper surface of the second refractive index layer 132. The plurality of second pore passages 132-2 of the second refractive index layer 132 may be in contact with the lower surface of the second color conversion layer 142.

The second color conversion particles 142a may be included in the second color conversion layer 142, and the second color conversion particles 142b may be disposed in the plurality of second pore passages 132-2 of the second refractive index layer 132. In this instance, the second color conversion particles 142a of the second color conversion layer 142 and the second color conversion particles 142b disposed in the plurality of second pore passages 132-2 of the second refractive index layer 132 may be in contact with each other on the upper surface of the second member 132-1). As will be described later, a second color conversion solution comprising the plurality of second color conversion particles 142a and 142b may be applied and cured on the second refractive index layer 132. Accordingly, some of the plurality of second color conversion particles 142a and 142b may be injected into and fixed through the plurality of pore passages 131-2 and 133-2 of the second refractive index layer 132, thereby remaining as second color conversion particles 142b. The remaining particles among the plurality of second color conversion particles 142a and 142b that are not injected into the plurality of second pore passages 132-2 of the second refractive index layer 132, i.e., the second color conversion particles 142a, may form the second color conversion layer 142 on the second refractive index layer 132.

The second color conversion solution may be formed by mixing a resin, a plurality of second color conversion particles 142a and 142b, an additive, etc.

The drawing illustrates that the upper surface of the first refractive index layer 131 has a straight surface, and that the upper surface of the first color conversion layer 141 also has a straight surface parallel to the upper surface of the first refractive index layer 131, but is not limited thereto. The drawing illustrates that the upper surface of the second refractive index layer 132 has a straight surface, and that the upper surface of the second color conversion layer 142 also has a straight surface parallel to the upper surface of the second refractive index layer 132, but is not limited thereto.

Meanwhile, the color conversion layer 140 may have a thickness W2 that is 1/10 or less of a thickness W1 of the refractive index layer 130. For example, the first color conversion layer 141 may have a thickness that is 1/10 or less of a thickness of the first refractive index layer 131. For example, the second color conversion layer 142 may have a thickness less than or equal to 1/10 of a thickness of the second refractive index layer 132. In addition, the light-transmitting layer 150 may have a thickness less than or equal to 1/10 of a thickness W1 of the refractive index layer 130. For example, the light-transmitting layer 150 may have a thickness less than or equal to 1/10 of a thickness of the third refractive index layer 133.

Meanwhile, in the embodiment, the refractive index layer 130 may also be used as the color conversion layer 140. In this instance, the refractive index layer 130 may be named a first color conversion layer, and the color conversion layer 140 may be named a second color conversion layer. In this instance, the first refractive index layer 131 may be named a first-first color conversion layer, and the first color conversion layer 141 of the color conversion layer 140 may be named a first-second color conversion layer. In addition, the second refractive index layer 132 may be named as a second-first color conversion layer, and the second color conversion layer 142 of the color conversion layer 140 may be named as a second-second color conversion layer.

According to an embodiment, by performing color conversion at least twice, the color conversion efficiency can be significantly improved, thereby improving the luminance. That is, the first color light may be primarily converted into the second color light or the third color light in the refractive index layer 130, and the first color light that is not color-converted in the refractive index layer 130 may be secondarily converted into the second color light or the third color light in the color conversion layer 140. In particular, since the first color light is scattered or reflected in more diverse directions by the three-dimensionally curved plurality of pore passages 131-2 and 133-2 in the refractive index layer 130, a probability of the first color light being color-converted into the second color light or the third color light may increase, so that the first color light may be more converted into the second color light or the third color light, and thus the luminance can be improved.

Meanwhile, the display device 100 according to the embodiment may comprise a light-transmitting layer 150.

The light-transmitting layer 150 may be disposed on the third refractive index layer 133. The light-transmitting layer 150 may transmit the first color light of the third semiconductor light-emitting element 123. The light-transmitting layer 150 may be formed of a material having excellent transmittance, for example, an inorganic material, an organic material, or a resin such as epoxy.

Meanwhile, the display device 100 according to the embodiment may comprise a bank 170. The bank 170 may be called a partition wall, a black matrix, a side wall, a barrier, etc.

The bank 170 may be disposed between the first refractive index layer 131, the second refractive index layer 132, and the third refractive index layer 133. A height (or thickness) of the bank 170 may be greater than a height (or thickness) of each of the first refractive index layer 131, the second refractive index layer 132, and the third refractive index layer 133. For example, the height of the bank 170 may be equal to the sum of the height of the first refractive index layer 131 and the height of the first color conversion layer 141, but is not limited thereto. For example, the height of the bank 170 may be equal to the sum of the height of the second refractive index layer 132 and the height of the second color conversion layer 142, but is not limited thereto. For example, the height of the bank 170 may be equal to the sum of the height of the third refractive index layer 133 and the height of the light-transmitting layer 150, but is not limited thereto.

Meanwhile, the display device 100 according to the embodiment may comprise a protective layer 180. The protective layer 180 may be called an encapsulation layer, an insulating layer, etc.

The protective layer 180 may be disposed on the color conversion layer 140. The protective layer 180 may be disposed on the first color conversion layer 141. The protective layer 180 may be disposed on the second color conversion layer 142. The protective layer 180 may be disposed on the light-transmitting layer 150. In addition, the protective layer 180 may be disposed on the bank 170.

The protective layer 180 may be formed by depositing an inorganic material by sputtering or by depositing an organic material by spin coating. The protective layer 180 may also be formed by using a pre-prepared insulating film. For example, the insulating film may be attached to the color conversion layer 140 and/or the bank 170 by using an adhesive, but is not limited thereto.

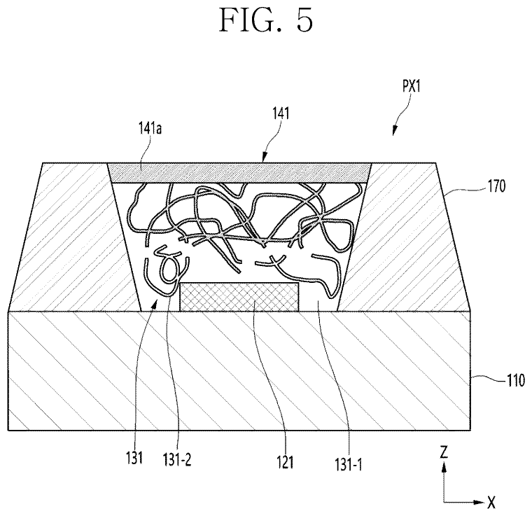

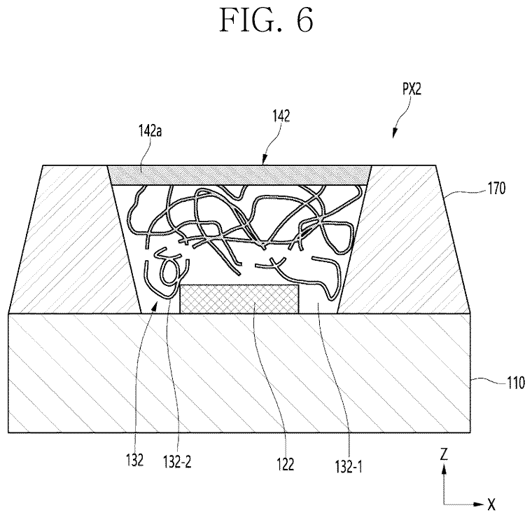

FIG. 5 is a second cross-sectional view illustrating PX1 of FIG. 2 in detail. FIG. 6 is a second cross-sectional view illustrating PX2 of FIG. 2 in detail.

FIGS. 5 and 6 illustrate a structure in which, unlike FIGS. 3 and 4, color conversion particles may be disposed on a part of the refractive index layer 130, for example, on ab upper side of the refractive index layer 130, and color conversion particles are not disposed on a lower side of the refractive index layer 130.

As illustrated in FIGS. 2, 5, and 7, the refractive index layer 130 may comprise a first refractive index layer 131, a second refractive index layer 132, and a third refractive index layer 133.

As described above, the first refractive index layer 131, the second refractive index layer 132, and the third refractive index layer 133 may each comprise a plurality of pore passages 131-2 and 133-2 having a three-dimensionally curved shape. Here, the three-dimensionally curved shape may mean that each of the plurality of pore passages 131-2 and 133-2 is disposed along at least two directions among a X-axis direction, a Y-axis, a Z-axis direction, a diagonal direction, a gravity direction, a direction against gravity, a horizontal direction, a clockwise direction, or a counterclockwise direction. Accordingly, the plurality of pore passages 131-2 and 133-2 may be connected to each other, may be isolated from each other, and may be disposed in a horizontal direction, a vertical direction, a diagonal direction, a zigzag direction, etc.

The first refractive index layer 131 may be disposed on at least one or more first semiconductor light-emitting element 121 in the first subpixel PX1, the second refractive index layer 132 may be disposed on at least one or more second semiconductor light-emitting element 122 in the second subpixel PX2, and the third refractive index layer 133 may be disposed on at least one or more third semiconductor light-emitting element 123 in the third subpixel PX3.

For example, the first refractive index layer 131 may comprise a plurality of first pore passages 131-2 having a three-dimensionally curved shape, the second refractive index layer 132 may comprise a plurality of second pore passages 132-2 having a three-dimensionally curved shape, and the third refractive index layer 133 may comprise a plurality of third pore passages 133-2 having a three-dimensionally curved shape.

A plurality of first color conversion particles 141b and a plurality of second color conversion particles 142b may be disposed in the plurality of first pore passages 131-2 and the plurality of second pore passages 132-2 each having such a structure.

As will be described later, a solution comprising a plurality of first color conversion particles 141a and 141b may be applied and cured on the first refractive index layer 131, so that some 141b among the first color conversion particles 141a and 141b may be injected into the plurality of first pore passages 131-2 of the first refractive index layer 131, and a first color conversion layer 141 may be formed by the remaining first color conversion particles 141a that are not injected into the plurality of first pore passages 131-2 among the first color change particles. Another color conversion layer may be formed by the first color conversion particles 141b injected into the plurality of first pore passages 131-2 of the first refractive index layer 131. Accordingly, the first refractive index layer 131 may be divided into a refractive index layer 130 and a color conversion layer, or the refractive index layer 130 may comprise the color conversion layer.

As described above, since the plurality of first pore passages 131-2 of the first refractive index layer 131 are three-dimensionally curved, the plurality of first color conversion particles 141b may be injected into the plurality of first pore passages 131-2 through the plurality of first pore passages 131-2 connected to the upper surface of the first refractive index layer 131, that is, the upper surface of the first member 131-1. The plurality of first color conversion particles 141b injected in this manner may descend downward by gravity.

However, when the plurality of first pore passages 131-2 inside the first refractive index layer 131 are oriented from the upper direction to the lower direction and then again to the upper direction, it is easy for the plurality of first color conversion particles 141b to descend from the upper direction to the lower direction through the plurality of first pore passages 131-2, but it is difficult for the plurality of first color conversion particles 141b to ascend from the lower direction to the upper direction. In other words, it is difficult for the plurality of first color conversion particles 141b to ascend from the lower direction to the upper direction against gravity.

Among the plurality of first pore passages 131-2 disposed in the first refractive index layer 131, the plurality of first color conversion particles 141b may be disposed in the plurality of first pore passages 131-2 corresponding to the upper side of the first refractive index layer 131, and the plurality of first color conversion particles 141b are not disposed in the plurality of first pore passages 131-2 corresponding to a lower side of the first refractive index layer 131. Accordingly, the plurality of first color conversion particles 141b may be spaced apart from at least one or more first semiconductor light-emitting element 121. The plurality of first pore passages 131-2, where the plurality of first color conversion particles 141b are not disposed, may be filled with air or maintained in a vacuum state, but is not limited thereto.

For example, the first refractive index layer 131 may comprise at least a first refractive index region 131a adjacent to the first semiconductor light-emitting element 121 and a second refractive index region 131b on the first refractive index region 131a. In this instance, the first color conversion particles 141b may be disposed in a pore passage on the second refractive index region 131b. In this instance, the pore passage of the first refractive index region 131a may be filled with air 131_air, but is not limited thereto.

Meanwhile, when at least one or more first semiconductor light-emitting elements 121 continuously emit first color light, heat may be generated in at least one or more first semiconductor light-emitting elements 121, and the heat may affect the first color conversion particles 141b. For example, the heat may cause a wavelength shift of the first color conversion particle 141b, causing it to be converted into a second color light of a different wavelength than the desired wavelength.

However, as in the structure described above, since the plurality of first color conversion particles 141b are spaced apart from at least one or more first semiconductor light-emitting element 121, even if heat is generated from at least one or more first semiconductor light-emitting element 121, the heat of the at least one or more first semiconductor light-emitting element 121 is not transferred to the plurality of first color conversion particles 141b, so that the plurality of first color conversion particles 141b may be converted into a second color light of a wavelength that matches its unique characteristics. That is, defects such as wavelength shift can be prevented.

Similarly, a second color conversion solution comprising a plurality of second color conversion particles 142a and 142b may be applied and cured on the second refractive index layer 132, so that some 142b among the second color conversion particles 142a and 142b may be injected into the plurality of second pore passages 132-2 of the second refractive index layer 132, and a second color conversion layer 142 may be formed by the remaining second color conversion particles 142a that are not injected into the plurality of second pore passages 132-2 among the second color changing particles. Another color conversion layer may be formed by the second color conversion particles 142b injected into the plurality of second pore passages 132-2 of the second refractive index layer 132. Accordingly, the second refractive index layer 132 may be divided into a refractive index layer 130 and a color conversion layer, or the refractive index layer 130 may comprise the color conversion layer.

As described above, since the plurality of second pore passages 132-2 of the second refractive index layer 132 are three-dimensionally curved, the plurality of second color conversion particles 142b may be injected into the plurality of second pore passages 132-2 through the plurality of second pore passages 132-2 connected to the upper surface of the second refractive index layer 132, that is, the upper surface of the second member 132-1. The plurality of second color conversion particles 142b injected in this manner may descend downward by gravity.

However, when the plurality of second pore passages 132-2 inside the second refractive index layer 132 are oriented from the upper direction to the lower direction and then again to the upper direction, it is easy for the plurality of second color conversion particles 142b to descend from the upper direction to the lower direction through the plurality of second pore passages 132-2, but it is difficult for the plurality of second color conversion particles 142b to ascend from the lower direction to the upper direction. In other words, it is difficult for the plurality of second color conversion particles 142b to ascend from the lower direction to the upper direction against gravity.

Among the plurality of second pore passages 132-2 disposed in the second refractive index layer 132, the plurality of second color conversion particles 142b may be disposed in the plurality of second pore passages 132-2 corresponding to the upper side of the second refractive index layer 132, and the plurality of second color conversion particles 142b are not disposed in the plurality of second pore passages 132-2 corresponding to a lower side of the second refractive index layer 132. The plurality of second pore passages 132-2, where the plurality of second color conversion particles 142b are not disposed, may be filled with air or maintained in a vacuum state, but is not limited thereto.

For example, the second refractive index layer 132 may comprise at least a first refractive index region 132a adjacent to the second semiconductor light-emitting element 122 and a second refractive index region 132b on the first refractive index region 132a. In this instance, the second color conversion particles 142b may be disposed in the pore passage on the second refractive index region 132b. In this instance, the pore passage of the first refractive index region 132a may be filled with air 132_air, but is not limited thereto.

Meanwhile, when at least one or more second semiconductor light-emitting element 122 continuously emits first color light, heat may be generated from at least one or more second semiconductor light-emitting element 122, and the heat may affect the second color conversion particles 142b. For example, the heat can may cause a wavelength shift in the second color conversion particle 142b, causing it to be converted into a third color light of a different wavelength than the desired wavelength.

However, as in the structure described above, since the plurality of second color conversion particles 142b are spaced apart from at least one or more second semiconductor light-emitting element 122, even if heat is generated from at least one or more second semiconductor light-emitting element 122, the heat of the at least one or more second semiconductor light-emitting element 122 is not transferred to the plurality of second color conversion particles 142b, so that the plurality of second color conversion particles 142b may be converted into light of a third color having a wavelength that matches its unique characteristics. That is, defects such as wavelength shift can be prevented.

Meanwhile, since the first color light emitted from at least one or more third semiconductor light-emitting element 123 in the third subpixel PX3 is emitted as is and the first color light does not need to be color-converted into another color light, no color conversion particles may be disposed inside the third refractive index layer 133 or on the third refractive index layer 133. In this instance, the plurality of third pore passages 133-2 disposed in the third refractive index layer 133 may be filled with air or maintained in a vacuum state, but is not limited thereto.

### Light Propagation in a Plurality of Subpixels

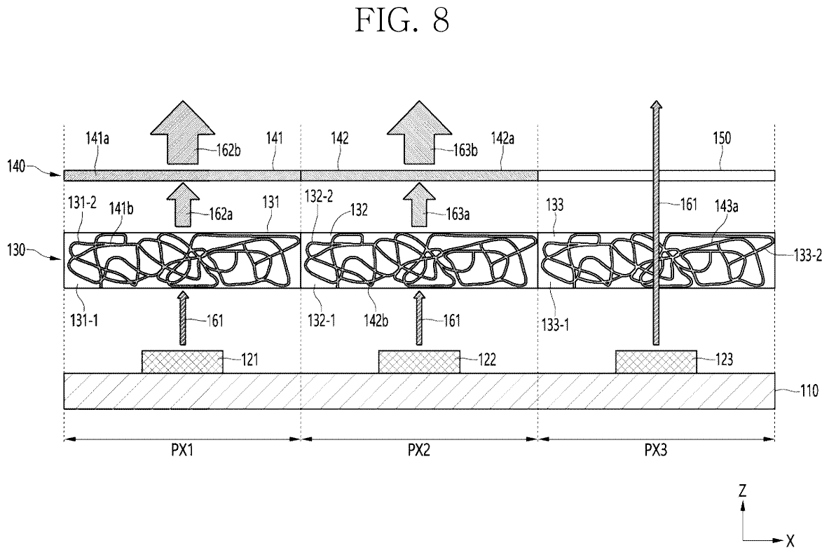

FIG. 8 illustrates a state in which a first color light, a second color light, and a third color light propagation in a display device according to an embodiment.

As illustrated in FIG. 8, the first subpixel PX1, the second subpixel PX2, and the third subpixel PX3 may be defined on the substrate 110. Although only the first subpixel PX1, the second subpixel PX2, and the third subpixel PX3 constituting the unit pixel are illustrated in the drawing, a plurality of pixels having the first subpixel PX1, the second subpixel PX2, and the third subpixel PX3 as unit pixels may be defined on the substrate 110. The pixels may be arranged in a matrix, but are not limited thereto.

An image may be displayed by color lights output from the first subpixel PX1, the second subpixel PX2, and the third subpixel PX3. For example, the first subpixel PX1 may output the second color light 162b, the second subpixel PX2 may output the third color light 163b, and the third subpixel PX3 may output the first color light 161.

A plurality of semiconductor light-emitting elements, that is, at least one or more first semiconductor light-emitting element, at least one or more second semiconductor light-emitting element 122, and at least one or more third semiconductor light-emitting element 123, may be disposed on a substrate 110. A refractive index layer 130 may be disposed on the plurality of semiconductor light-emitting elements, and a color conversion layer 140 may be disposed on the refractive index layer 130. The refractive index layer 130 may comprise a first refractive index layer 131 on at least one or more first semiconductor light-emitting element 121, a second refractive index layer 132 on at least one or more second semiconductor light-emitting element 122, and a third refractive index layer 133 on at least one or more third semiconductor light-emitting element 123. The color conversion layer 140 may comprise a first color conversion layer 141 on the first refractive index layer 131 and a second color conversion layer 142 on the second refractive index layer 132. Meanwhile, a light-transmitting layer 150 may be disposed on the third refractive index layer 133, but is not limited thereto.

In this instance, the first subpixel PX1 may comprise at least one or more first semiconductor light-emitting element 121, a first refractive index layer 131, and a first color conversion layer 141. The first semiconductor light-emitting element 121, the first refractive index layer 131, and the first color conversion layer 141 may be in contact with or spaced apart from each other. The second subpixel PX2 may comprise at least one or more second semiconductor light-emitting element 122, a second refractive index layer 132, and a second color conversion layer 142. The at least one or more second semiconductor light-emitting element 122, the second refractive index layer 132, and the second color conversion layer 142 may be in contact with or spaced apart from each other. The third subpixel PX3 may comprise at least one or more third semiconductor light-emitting element 123 and a third refractive index layer 133. The light-transmitting layer 150 may also be included in the third subpixel PX3.

According to an embodiment, light emitted from a light source may be color-converted to output various color lights, thereby allowing a desired image to be displayed.

For example, the first semiconductor light-emitting element 121, the second semiconductor light-emitting element 122, and the third semiconductor light-emitting element 123 may, as light sources, emit the same color light (first color light 161), that is, blue light.

### Light Propagation in the First Subpixel PX1

The first color light 161 emitted from at least one or more first semiconductor light-emitting element 121 may be incident on the first refractive index layer 131.

The first color light 161 may be refracted or diffusely reflected by the plurality of first pore passages 131-2 that are three-dimensionally curved in the first refractive index layer 131, and may propagate to the entire region of the first refractive index layer 131 rather than passing through the first refractive index layer 131. Meanwhile, the plurality of first pore passages 131-2 may be disposed in the entire region of the first refractive index layer 131, and the first color conversion particles 141b may be disposed in the plurality of first pore passages 131-2. Accordingly, the first color light 161 may propagate to the entire region of the first refractive index layer 131, and may be converted into the second color light 162a by the first color conversion particles 141b disposed on the entire region of the first refractive index layer 131, so that the color conversion efficiency can be improved.

That is, the plurality of first pore passages 131-2 disposed in the entire region of the first refractive index layer 131 may allow the first color light 161 incident on the first refractive index layer 131 to remain in the first refractive index layer 131 for as long as possible without being emitted forward through the first refractive index layer 131 immediately. In addition, since the first color conversion particles 141b are disposed in the plurality of first pore passages 131-2 disposed in the entire region of the first refractive index layer 131, the first color light 161 may be converted into the second color light 162a in the entire region of the first refractive index layer 131, so that the color conversion efficiency can be improved.

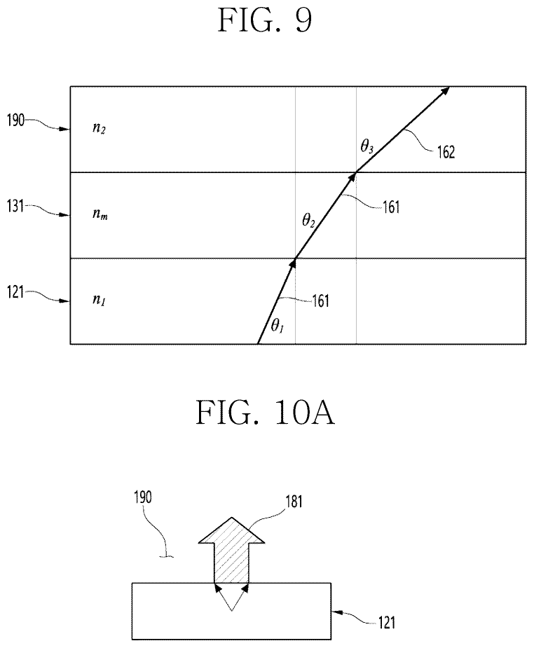

Meanwhile, as illustrated in FIG. 9, the first refractive index layer 131 may be made of a medium that has a refractive index nₘ smaller than a refractive index n₁ of the first semiconductor light-emitting element 121 and greater than a refractive index (n₂=1) of an atmospheric layer 190, so that a total internal reflection area may be reduced to increase the light extraction efficiency, thereby improving the luminance. The atmospheric layer 190 may be an atmospheric layer positioned in front of the display device 100 according to the embodiment, but is not limited thereto.

The larger the refractive index difference between the two media, the larger the critical angle, and the larger the critical angle, the larger the total internal reflection area. As the total internal reflection area increases, the area where light passing through the first medium cannot enter the second medium and is reflected back to the first medium increases, so that the light extraction efficiency may be reduced. When the light extraction efficiency decreases, the light efficiency or the luminance decreases.

To solve this problem, in an embodiment, the refractive index nₘ of the first refractive index layer 131 may be made smaller than the refractive index n₁ of the first semiconductor light-emitting element 121 and larger than the refractive index n₂ of the atmospheric layer 190, so that the total internal reflection area can be reduced.

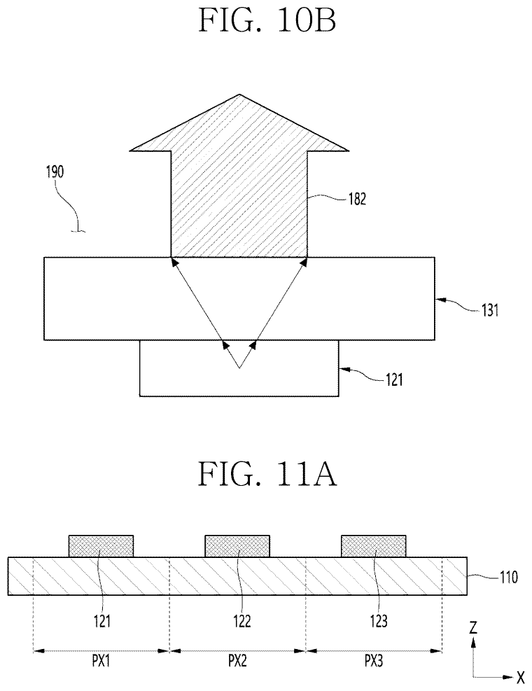

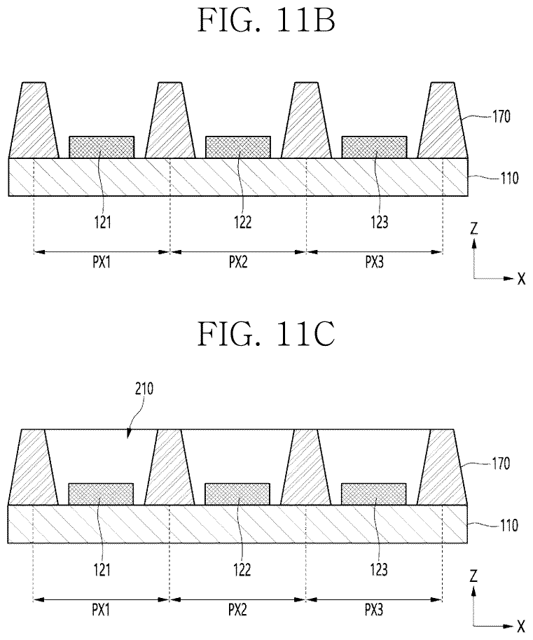

As illustrated in FIG. 10A, when the first refractive index layer 131 (and the first color conversion layer 141) is omitted, that is, when the first semiconductor light-emitting element 121 is directly exposed to the atmospheric layer 190, the difference in the refractive index of the first semiconductor light-emitting element 121 and the refractive index of the atmospheric layer 190 is large, and accordingly, the total internal reflection area also increases. In this instance, the first color light 161 of the first semiconductor light-emitting element 121 is not emitted to the atmospheric layer 190 but is reflected into the inside of the first semiconductor light-emitting element 121 by total internal reflection, so that a relatively small amount of light 181 may be output.

As illustrated in FIG. 10B, when the first refractive index layer 131 (and the first color conversion layer 141) is disposed between the first semiconductor light-emitting element 121 and the atmospheric layer 190, and the refractive index of the first refractive index layer 131 is smaller than the refractive index of the first semiconductor light-emitting element 121 and greater than the refractive index of the atmospheric layer 190, the total internal reflection area may be reduced.

In this instance, the first color light 161 of the first semiconductor light-emitting element 121 may be more incident on the first refractive index layer 131, and the second color light 162a color-converted in the first refractive index layer 131 may be more emitted into the atmospheric layer 190. In other words, the second color light 162a may be output to the atmospheric layer 190 with a greater amount of light 182.

As illustrated in FIG. 9, at the boundary between the first semiconductor light-emitting element 121 and the first refractive index layer 131, the first color light 161 of the first semiconductor light-emitting element 121 may be incident at an incident angle θ1 and refracted at a refraction angle θ2 to be incident on the first refractive index layer 131. The first color light 161 may be color-converted into the second color light 162 in the first refractive index layer 131. The second color light 162 may be incident at an incident angle θ2 and refracted at a refraction angle θ3 to be output to the atmospheric layer 190 at the boundary between the first refractive index layer 131 and the atmospheric layer 190.

When the refractive index of the first refractive index layer 131 is smaller than the refractive index of the first semiconductor light-emitting element 121 and greater than the refractive index of the atmospheric layer 190, the refraction angle θ2 and the refraction angle θ3 may be each reduced so that the first color light 161 may be more incident on the first refractive index layer 131, and the second color light 162 may be more output to the atmospheric layer 190. In other words, by disposing the first refractive index layer 131 (and the first color conversion layer 141) between the first semiconductor light-emitting element 121 and the atmospheric layer 190, the extraction efficiency of the second color light 162 can be improved, so that the luminance can be improved.

Meanwhile, not only the second color light 162a but also other color light, for example, the first color light 161 or another light shifted in wavelength from the first color light 161 (hereinafter referred to as “wavelength-shifted first light”), may be incident on the first color conversion layer 141 from the first refractive index layer 131. The first color conversion layer 141 may be composed of first color conversion particles 141a. These first color conversion particles 141a may be in contact with each other or spaced apart from each other. For example, the first color conversion layer 141 may be formed by a plurality of first color conversion particles 141a, a resin, and an additive, but is not limited thereto.

The first color conversion layer 141 has a very thin thickness, for example, a thickness of 1/10 or less of the thickness of the first refractive index layer 131, so that the second color light 162a incident from the first refractive index layer 131 may be transmitted as is and output toward the front. In contrast, the first color light 161 or the wavelength-shifted first light may be converted into the second color light 162b by the plurality of first color conversion particles 141a of the first color conversion layer 141, so that the color conversion efficiency can be improved. That is, since conversion to the second color light 162b is performed not only in the first refractive index layer 131 but also in the first color conversion layer 141, the color conversion efficiency can be improved.

In addition, since the thickness of the first color conversion layer 141 is thin, self-aggregation of the plurality of first color conversion particles 141a constituting the first color conversion layer 141 may be minimized, so that the first color conversion particles 141a in the first color conversion layer 141 can have excellent quality without defects, thereby maximizing the color conversion efficiency.

According to an embodiment, in the first subpixel PX1, the first refractive index layer 131 comprising a plurality of first pore passages 131-2 and first color conversion particles 141b and the first color conversion layer 141 configured on the first refractive index layer 131 can improve light extraction efficiency by reducing the total internal reflection area by the first refractive index layer 131. In a wider region of the first refractive index layer 131, the first color light 161 may be converted into the second color light 162a, thereby improving the light efficiency and the luminance of the second color light 162a, and the color conversion efficiency of the first color light 161 converted into the second color light 162a in the first refractive index layer 131 can be improved. In particular, color conversion into second color lights 162a and 162b may be performed in each of the first refractive index layer 131 and the first color conversion layer 141, so that the light efficiency and the luminance can be significantly improved.

### Light Propagation in the Second Subpixel PX2

The first color light 161 emitted from at least one or more second semiconductor light-emitting element 122 may be incident on the second refractive index layer 132.

The first color light 161 may be refracted or diffusely reflected by a plurality of second pore passages 132-2 that are three-dimensionally curved in the second refractive index layer 132 and may propagate to the entire region of the second refractive index layer 132 rather than passing through the second refractive index layer 132. Meanwhile, the plurality of second pore passages 132-2 may be disposed in the entire region of the second refractive index layer 132, and second color conversion particles 142b may be disposed in the plurality of second pore passages 132-2. Accordingly, since the first color light 161 may propagate to the entire region of the second refractive index layer 132, and may be converted into the third color light 163a by the second color conversion particles 142b disposed on the entire region of the second refractive index layer 132, so that the color conversion efficiency can be improved.

That is, the plurality of second pore passages 132-2 disposed in the entire region of the second refractive index layer 132 may allow the first color light incident on the second refractive index layer 132 to remain in the second refractive index layer 132 for as long as possible without being emitted forward through the second refractive index layer 132 immediately. In addition, since the second color conversion particles 142b are disposed in the plurality of second pore passages 132-2 disposed in the entire region of the second refractive index layer 132, the first color light 161 may be converted into the third color light 163a in the entire region of the second refractive index layer 132, so that the color conversion efficiency can be improved.

Meanwhile, although not illustrated, the second refractive index layer 132 may be made of a medium that has a refractive index smaller than a refractive index of the second semiconductor light-emitting element 122 and greater than a refractive index of the atmospheric layer 190, so that the total internal reflection area may be reduced to increase the light extraction efficiency, thereby improving the luminance. The atmospheric layer may be an atmospheric layer positioned in front of the display device 100 according to the embodiment, but is not limited thereto.

For example, since the refraction angle of the second refractive index layer 132 is reduced between the second semiconductor light-emitting element 122 and the second refractive index layer 132, the first color light 161 emitted from the second semiconductor light-emitting element 122 may be more incident on the second refractive index layer 132. In addition, since the refraction angle of the atmospheric layer is reduced between the second refractive index layer 132 and the atmospheric layer 190, the third color light 163a color-converted in the second refractive index layer 132 may be more output to the atmospheric layer 190. In other words, the extraction efficiency of the third color light 163a can be increased, so that the luminance can be improved.

Meanwhile, not only the third color light 163a but also other color light, for example, the first color light 161 or another light shifted in wavelength from the first color light 161 (hereinafter referred to as wavelength-shifted second light), may be incident on the second color conversion layer 142 from the second refractive index layer 132. The second color conversion layer 142 may be composed of second color conversion particles 142a. These second color conversion particles 142a may be in contact with each other or spaced apart from each other. For example, the second color conversion layer 142 may be formed by a plurality of second color conversion particles 142a, a resin, and an additive, but is not limited thereto.

The second color conversion layer 142 has a very thin thickness, for example, a thickness of 1/10 or less than of the thickness of the second refractive index layer 132, so that the third color light 163a incident from the second refractive index may be transmitted as is and output toward the front. In contrast, the first color light 161 or the wavelength-shifted second light may be converted into the third color light 163b by the plurality of second color conversion particles 142a of the second color conversion layer 142, so that the color conversion efficiency can be improved. That is, since the conversion into the third color lights 163a and 163b is performed not only in the second refractive index layer 132 but also the second color conversion layer 142, the color conversion efficiency can be improved.

In addition, since the thickness of the second color conversion layer 142 is thin, self-aggregation of the plurality of second color conversion particles 142a constituting the second color conversion layer 142 may be minimized, so that the second color conversion particles 142a in the second color conversion layer 142 can have excellent quality without defects, thereby maximizing the color conversion efficiency.

According to an embodiment, in the second sub-pixel PX2, a second refractive index layer 132 including a plurality of second pore passages 132-2 and second color conversion particles 142b and the second color conversion layer 142 configured on the second refractive index layer 132 can improve the light extraction efficiency by reducing the total reflection area by the second refractive index layer 132. In a wider region of the second refractive index layer 132, the first color light 161 may be converted into the third color light 163a, thereby improving the light efficiency and the luminance of the third color light 163a, and the color conversion efficiency of the first color light 161 converted into the third color light 163a in the second refractive index layer 132 can be improved. In particular, color conversion to the third color light 163b may be performed in each of the second refractive index layer 132 and the second color conversion layer 142, so that the light efficiency and the luminance can be significantly improved.

### Light Propagation in the Third Subpixel PX3

The first color light 161 emitted from at least one or more third semiconductor light-emitting element 123 may be incident on the third refractive index layer 133.

The first color light 161 may be refracted or diffusely reflected by a plurality of third pore passages 133-2 that are three-dimensionally curved in the third refractive index layer 133, and may propagate to the entire region of the third refractive index layer 133 rather than passing through the third refractive index layer 133. Meanwhile, the plurality of third pore passages 133-2 may be disposed in the entire region of the third refractive index layer 133. Accordingly, the first color light 161 may be evenly output in the entire region of the third refractive index by being refracted or diffusely reflected by the plurality of third pore passages 133-2 disposed over the entire region of the third refractive index layer.

Meanwhile, although not illustrated, the third refractive index layer 133 may be made of a medium that has a refractive index smaller than a refractive index of the third semiconductor light-emitting element 123 and greater than a refractive index of the atmospheric layer 190, so that the total internal reflection area and increasing the light extraction efficiency may be reduced, thereby improving the luminance. The atmospheric layer may be an atmospheric layer positioned in front of the display device 100 according to the embodiment, but is not limited thereto.

For example, since the refraction angle of the third refractive index layer 133 is reduced between the third semiconductor light-emitting element 123 and the third refractive index layer 133, the first color light 161 emitted from the third semiconductor light-emitting element 123 may be more incident on the third refractive index layer 133. In addition, since the refraction angle of the atmospheric layer is reduced between the third refractive index layer 133 and the atmosphere, the first color light 161 that has passed through the third refractive index layer 133 may be more output to the atmospheric layer 190. In other words, the extraction efficiency of the first color light 161 can be increased, so that the luminance can be improved.

Meanwhile, since the refractive index of the light-transmitting layer 150 is set to be smaller than the refractive index of the third refractive index and greater than the refractive index of the atmosphere, the total internal reflection area of the light-transmitting layer 150 may be reduced, so that the extraction efficiency of the first color light 161 can be improved, thereby improving the luminance.

Meanwhile, although a color filter layer is not illustrated in FIG. 2, the color filter layer may be disposed on the color conversion layer 140, but is not limited thereto. For example, the color filter layer may comprise a first color filter, a second color filter, and a third color filter. The first color filter may be disposed on the first color conversion layer 141 in the first subpixel PX1, the second color filter may be disposed on the second color conversion layer 142 in the second subpixel PX2, and the third color filter may be disposed on the light-transmitting layer 150 in the third subpixel PX3.

The first color filter may output only second color light having a preset second wavelength band. Accordingly, among the second color lights 162b emitted through the first color conversion layer 141, second color light outside the second wavelength band is removed by the first color filter and cannot be output forward. The second color filter may output only third color light having a preset third wavelength band. Accordingly, among the third color light 163b emitted through the second color conversion layer 142, third color light outside the third wavelength band is removed by the second color filter and cannot be output forward. The third color filter may output only first color light having a preset first wavelength band. Accordingly, among the first color light output through the light-transmitting layer 150, first color light outside the first wavelength band is removed by the third color filter and cannot be output forward.

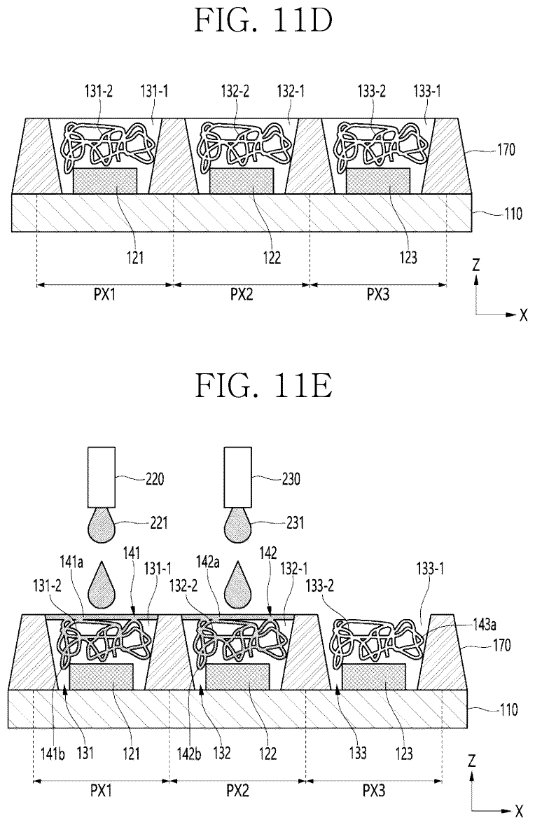

FIGS. 11A to 11F illustrate a manufacturing process of a display device according to an embodiment.

As illustrated in FIG. 11A, a plurality of semiconductor light-emitting elements 121 to 123 may be formed on a substrate 110.

The plurality of semiconductor light-emitting elements may be transferred onto the substrate 110 using a pick-up and place method, but is not limited thereto. A bonding process may be performed so that the plurality of semiconductor light-emitting elements may be electrically connected to the substrate 110. Although not illustrated, a driving unit comprising a plurality of circuits and a circuit pattern (or line) may be formed on the substrate 110. In this instance, each of the plurality of semiconductor light-emitting elements may be connected to the circuit pattern and receive a signal (voltage signal or current signal) from the driving unit through the circuit pattern.

A first subpixel PX1, a second subpixel PX2, and a third subpixel PX3 may be defined on the substrate 110.

For example, at least one or more first semiconductor light-emitting element 121 may be formed on the first subpixel PX1, at least one or more second semiconductor light-emitting element 122 may be formed on the second subpixel PX2, and at least one or more third semiconductor light-emitting element 123 may be formed on the third subpixel PX3.

As illustrated in FIG. 11B, a bank 170 may be formed on a boundary region between the first subpixel PX1, the second subpixel PX2, and the third subpixel PX3. The bank 170 may be formed as a matrix having a lattice shape when viewed from above. In this instance, the first semiconductor light-emitting element 121, the second semiconductor light-emitting element 122, and the third semiconductor light-emitting element 123 may be formed within each lattice. A height (or thickness) of the bank 170 may be greater than a height (or thickness) of each of the first semiconductor light-emitting element 121, the second semiconductor light-emitting element 122, and the third semiconductor light-emitting element 123. Accordingly, a groove or recess surrounded by the bank 170 may be formed by the bank 170 formed at the boundary region between the first subpixel PX1, the second subpixel PX2, and the third subpixel PX3, and the first semiconductor light-emitting element 121, the second semiconductor light-emitting element 122, and the third semiconductor light-emitting element 123 may be formed in the groove, respectively.

As illustrated in FIG. 11C, a mixture 210 comprising an organometallic compound, a porogen, a metal oxide, deionized water, and an additive may be formed in each of the grooves formed by the bank 170 using spin coating. The porogen is a lump of particles having a specific shape and size used to create pores in a molded structure, and may be dissolved and removed by a post-processing process (thermal curing process, immersion removal process, etc.).

As illustrated in FIG. 11D, a curing process may be performed on the mixture 210 formed in each of the grooves, so that members 131-1 to 133-1 may be formed by the mixture 210 formed in each of the grooves. Accordingly, the first member 131-1 may be formed in the first subpixel PX1, the second member 132-1 may be formed in the second subpixel PX2, and the third member 133-1 may be formed in the third subpixel PX3. In addition, as the porogen are dissolved and removed, a plurality of pore passages 131-2 and 133-2 corresponding to the porogens may be formed. For example, a plurality of first pore passages 131-2 may be formed in a first member 131-1 in the first subpixel PX1, a plurality of second pore passages 132-2 may be formed in a second member 132-1 in the second subpixel PX2, and a plurality of third pore passages 133-2 may be formed in a third member 133-1 in the third subpixel PX3.

The formation of the members 131-1 to 133-1 and the removal of the porogens may be performed through separate processes. First, a thermal curing process may be performed, so that the first member 131-1, the second member 132-1, and the third member 133-1 may be formed in the grooves of the first subpixel PX1, the second subpixel PX2, and the third subpixel PX3, respectively. Thereafter, a thermal curing process or an immersion removal process is performed, so that the porogens of the first member 131-1, the second member 132-1, and the third member 133-1, respectively, are dissolved and removed. Thus, a plurality of first pore passages 131-2, a plurality of second pore passages 132-2, and a plurality of third pore passages 133-2 may be formed in the first member 131-1, the second member 132-1, and the third member 133-1, respectively.

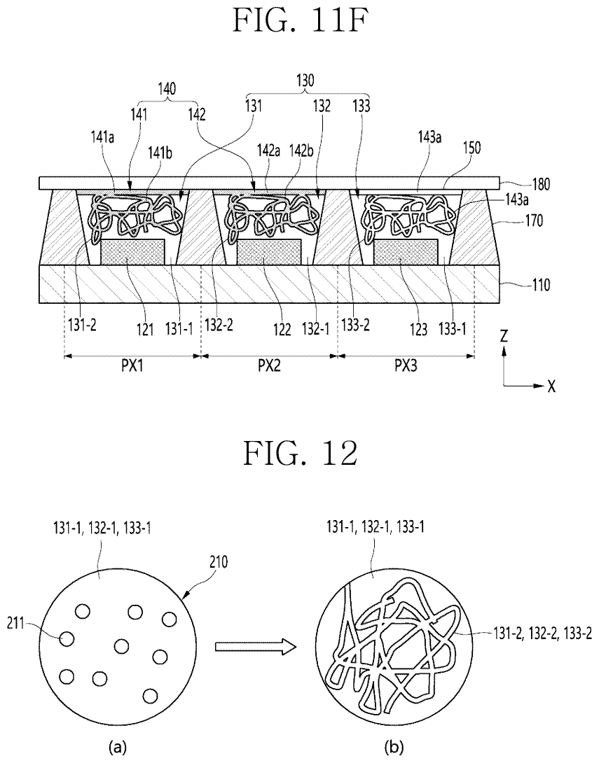

As illustrated in FIG. 12(a), a mixture 210 comprising an organometallic compound, a porogen 211, etc. may be applied to each of the grooves of the first subpixel PX1, the second subpixel PX2, and the third subpixel PX3, and then a curing process is performed, so that the first member 131-1, the second member 132-1, and the third member 133-1 may be formed. Thereafter, a curing process or an immersion removal process may be additionally performed on the first member 131-1, the second member 132-1, and the third member 133-1, so that the porogens 211 may be dissolved and removed. As illustrated in FIG. 12(b), regions where the porogen 211s are dissolved and removed may be formed as the first pore passage 131-2, the second pore passage 132-2, and the third pore passage 133-2, respectively. When a plurality of porogens 211 are formed to be connected to each other in the mixture 210, and these porogens 211 are dissolved and removed, a plurality of first pore passages 131-2, a plurality of second pore passages 132-2, and a plurality of third pore passages 133-2, which are three-dimensionally curved and connected to each other, may be formed.

Therefore, the first refractive index layer 131 may comprise the a first member 131-1 and a plurality of first pore passages 131-2, the second refractive index layer 132 may comprise a second member 132-1 and a plurality of second pore passages 132-2, and the third refractive index layer 133 may comprise a third member 133-1 and a plurality of third pore passages 133-2.

Meanwhile, the method for removing porogens 211 may be divided into two types according to the type. That is, in the case of polymers such as PEO-PPO diblock copolymers and PEO-PPO-PEO triblock copolymers, a process of removing porogens 211 may be performed by heating above the boiling point of porogen 211. In the case of porogens 211 such as NaCl, Sugar crystal, and gelatin, a process of removing porogens 211 through immersion removal may be performed.

The porous shape may be adjusted by adjusting the particle size and addition ratio of porogens 211, and preferably, an interconnected pore structure may be formed by mixing porogens 211 at a ratio of 10% or more.

The members 131-1 to 133-1, may be in the form of an organometallic compound, and the organometallic compound may be used as a precursor for forming TiO₂ or SiO₂. Based on a sol prepared by using other additives in a titanium(IV) isopropoxide-based organometallic compound, after curing, the members 131-1 to 133-1 having a refractive index of 1.7-2.2 and a transmittance of 70% or more can be formed. In the members 131-1 to 133-1, nano-sized TiO₂ or nano-sized SiO₂ exists, and the refractive index may be adjusted from 1.7 to 2.2 depending on the manufacturing content.

The members 131-1 to 133-1 may be formed by dispersing nano-sized TiO₂ or nano-sized SiO₂ in a silicone material. In addition, an acrylic-series or silicone-series polymer may be used as the members 131-1 to 133-1.

As illustrated in FIG. 11E, by performing an inkjet process, a first color conversion solution 221 and a second color conversion solution 231 may be applied to the first subpixel PX1 and the second subpixel PX2, respectively. The first color conversion solution 221 may be sprayed onto the first subpixel PX1 using a first inkjet spraying device 220, and the second color conversion solution 231 may be sprayed onto the second subpixel PX2 using a second inkjet spraying device 230.

The first color conversion solution 221 may be a mixture comprising a resin, a plurality of first color conversion particles 141a and 141b, an additive, etc. The second color conversion solution 231 may be a mixture comprising a resin, a plurality of second color conversion particles 142a and 142b, an additive, etc.

First, the first color conversion solution 221 may be applied to the groove of the first subpixel PX1. In this instance, after the first color conversion solution 221 is applied on the first refractive index layer 131, it may be injected into the plurality of first pore passages 131-2 of the first refractive index layer 131. Then, by performing a curing process, the first color conversion particles 141a and 141b may be disposed on the first refractive index layer 131 as well as the plurality of first pore passages 131-2 included in the first member 131-1 of the first refractive index layer 131. The first color conversion layer 141 may be formed by the first color conversion particles 141a disposed on the first refractive index layer 131.

The second color conversion solution 231 may be applied to the groove in the second subpixel PX2. In this instance, after the second color conversion solution 231 is applied on the second refractive index layer 132, it may be injected into the plurality of second pore passages 132-2 of the second refractive index layer 132. Then, by performing a curing process, the second color conversion particles 142a and 142b may be disposed on the second refractive index layer 132 as well as the plurality of second pore passages 132-2 included in the second member 132-1 of the second refractive index layer 132. The second color conversion layer 142 may be formed by the second color conversion particles 142a disposed on the second refractive index layer 132.

Meanwhile, the first color conversion particles 141b disposed in the plurality of first pore passages 131-2 may be included in the first refractive index layer 131. Alternatively, the first color conversion particles 141b disposed in the plurality of first pore passages 131-2 may be separated from the first refractive index layer 131 and may be separately formed as a color conversion layer separated from the first color conversion layer 141 disposed on the first refractive index layer 131. In this instance, the separated color conversion layer may become a first-first color conversion layer, and the first color conversion layer 141 may become a first-second color conversion layer, so that the first color conversion layer may be formed by the first-first color conversion layer and the first-second conversion layer.

In addition, the second color conversion particles 142b disposed in the plurality of second pore passages 132-2 may be included in the second refractive index layer 132. Alternatively, the second color conversion particles 142b disposed in the plurality of second pore passages 132-2 may be separately formed as a color conversion layer separated from the second refractive index layer 132 and separated from the second color conversion layer 142 disposed on the second refractive index layer 132. In this instance, the separated color conversion layer may become the second-first color conversion layer, and the second color conversion layer 142 may become the second-second color conversion layer, so that the second color conversion layer may be formed by the second-first color conversion layer and the second-second color conversion layer.

As illustrated in FIG. 11F, the protective layer 180 may be formed on the color conversion layer 140 and/or the bank 170. The protective layer 180 may also be formed on the transmission layer.

For example, the protective layer 180 may be formed by depositing an organic material by using sputtering or by using spin coating. For example, the protective layer 180 may be formed using a pre-prepared insulating film.

Meanwhile, as described above, according to the embodiment, the semiconductor light-emitting element may be transferred onto the substrate 110 using a pick-up and place method (FIG. 11A).

Alternatively, the semiconductor light-emitting element may be assembled onto the substrate 110 using a self-assembly process.

### Self-Assembly Process

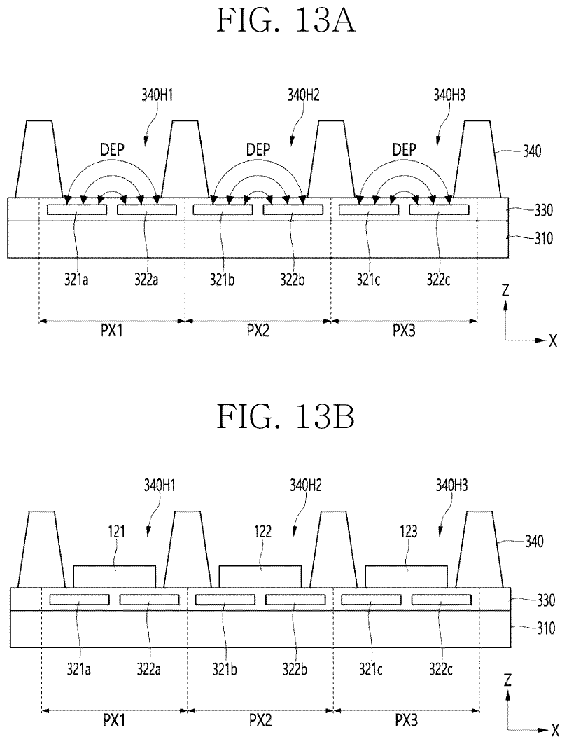

FIG. 13A and FIG. 13B illustrate a semiconductor light-emitting element being assembled using a self-assembly process.

As illustrated in FIG. 13A, a substrate 310 having a pair of assembly wirings 321a, 322a, 321b, 322b, 321c and 322c for forming a DEP force, and a partition wall 340 having assembly holes 340H1, 340H2 and 340H3 may be provided. Although not illustrated, a plurality of driving units and circuit patterns may be provided on the substrate 310.

A self-assembly method may be performed, so that a plurality of semiconductor light-emitting elements may be moved using magnets, and a plurality of semiconductor light-emitting elements may be assembled into a plurality of assembly holes 340H1, 340H2, and 340H3 on a substrate 310, respectively, using DEP force.

Although not illustrated, a fluid may be filled in the chamber, and a plurality of semiconductor elements may be put into the fluid. The substrate 310 may be disposed on the lower or upper side of the chamber and may come into contact with the fluid. Then, as the magnet is rotated or moved in a zigzag manner at the rear of the substrate 310, a plurality of semiconductor light-emitting elements may be magnetized, and the magnetized semiconductor light-emitting elements may be moved toward the magnet. Accordingly, the plurality of semiconductor light-emitting elements in the fluid may be moved to the respective assembly holes 340H1, 340H2, and 340H3 on the substrate 310 using the magnet. Then, an AC voltage may be applied to a pair of assembly wirings 321a, 322a, 321b, 322b, 321c, and 322c, so that a DEP force may be formed on one assembly wiring, that is, on the respective assembly holes 340H1, 340H2, and 340H3. As illustrated in FIG. 13B, a plurality of semiconductor light-emitting elements moved to the respective assembly holes 340H1, 340H2, and 340H3 may be pulled into the respective assembly holes 340H1, 340H2, and 340H3 by the DEP force of the respective assembly holes 340H1, 340H2, and 340H3 and assembled.

In FIGS. 13A and 13B, unexplained reference numeral 330 is an insulating layer, which may have a predetermined permittivity. The insulating layer 330 may protect a pair of assembly wirings 321a, 322a, 321b, 322b, 321c, and 322c, and may contribute to increasing the DEP force.

As illustrated in FIG. 13B, after a plurality of semiconductor light-emitting elements 121 to 123 are assembled on a substrate 310 using a self-assembly method, a refractive index layer 130 and a color conversion layer 140 as illustrated in FIG. 2 may be disposed on the plurality of semiconductor light-emitting elements 121 to 123 in the assembly holes 340H1, 340H2, and 340H3, and then a protective layer 180 may be disposed on the partition wall 340 and the color conversion layer 140, so that a display device capable of displaying an image may be configured.

Meanwhile, the display device described above may be a display panel. That is, in the embodiment, the display device and the display panel may be understood to have the same meaning. In the embodiment, the display device in a practical sense may comprise a display panel and a controller (or processor) capable of controlling the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### Industrial Applicability

The embodiment may be adopted in the display field for displaying images or information. The embodiment may be adopted in the display field for displaying images or information using a semiconductor light-emitting element. The semiconductor light-emitting element may be a micro-level semiconductor light-emitting element or a nano-level semiconductor light-emitting element.

For example, the embodiment may be adopted in a TV, signage, a smart phone, a mobile phone, a mobile terminal, a HUD for an automobile, a backlight unit for a laptop computer, and a display device for VR, AR or MR.

1. A display device, comprising:
a substrate;
a plurality of semiconductor light-emitting elements on the substrate;
a refractive index layer on the plurality of semiconductor light-emitting elements; and
a color conversion layer on the refractive index layer,
wherein the color conversion layer comprises color conversion particles,
wherein some of the color conversion particles are disposed in the refractive index layer,
wherein the refractive index layer comprises a plurality of pore passages, and
wherein some of the color conversion particles are disposed in the plurality of pore passages.

2. (canceled)

3. The display device of claim 1, wherein some of the color conversion particles are spaced from the plurality of semiconductor light-emitting elements.

4. The display device of claim 3, wherein the refractive index layer comprises:
a first refractive index region adjacent to the plurality of semiconductor light-emitting elements; and
a second refractive index region on the first refractive index region,
wherein some of the color conversion particles are disposed in the pore passages of the second refractive index region.

5. The display device of claim 4, comprising:
air in the pore passages of the first refractive index region.

6. The display device of claim 1, wherein the refractive index layer comprises a member, and
wherein the plurality of pore passages are disposed in the member.

7. The display device of claim 6, wherein the member comprises an organometallic compound, a metal oxide, deionized water, and an additive.

8. The display device of claim 1, wherein some among the plurality of pore passages is configured to be in contact with the plurality of semiconductor light-emitting elements through a lower surface of the member or be in contact with the color conversion layer through an upper surface of the member.

9. The display device of claim 8, wherein the color conversion particles of the color conversion layer and the color conversion particles of the plurality of pore passages are configured to be in contact with each other on the upper surface of the member.

10. The display device of claim 1, wherein the plurality of pore passages are three-dimensionally curved.

11. The display device of claim 10, wherein the plurality of pore passages are disposed along at least two directions among a X-axis direction, a Y-axis, a Z-axis direction, a diagonal direction, a gravity direction, a direction against gravity, a horizontal direction, a clockwise direction, or a counterclockwise direction.

12. The display device of claim 1, wherein each of the plurality of pore passages has a width that is at least twice or more a size of the color conversion particle.

13. The display device of claim 1, wherein the substrate comprises a first subpixel, a second subpixel, and a third subpixel,
wherein the plurality of semiconductor light-emitting elements comprise:
at least one or more first semiconductor light-emitting element in the first subpixel;
at least one or more second semiconductor light-emitting element in the second subpixel; and
at least one or more third semiconductor light-emitting element in the third subpixel, and
wherein the first semiconductor light-emitting element, the second semiconductor light-emitting element and the third semiconductor light-emitting element are configured to generate first color light.

14. The display device of claim 13, wherein the refractive index layer comprises:
a first refractive index layer on the at least one or more first semiconductor light-emitting element;
a second refractive index layer on the at least one or more second semiconductor light-emitting element; and
a third refractive index layer on the at least one or more third semiconductor light-emitting element, and
wherein a refractive index of each of the first refractive index layer, the second refractive index layer, and the third refractive index layer is smaller than a refractive index of the first semiconductor light-emitting element.

15. The display device of claim 14, wherein the color conversion layer comprises:
a first color conversion layer comprising first color conversion particles that convert the first color light into second color light on the first refractive index layer; and
a second color conversion layer comprising second color conversion particles that convert the first color light into third color light on the second refractive index layer.

16. The display device of claim 15, wherein some of the first color conversion particles are disposed in the first refractive index layer, and some of the second color conversion particles are disposed in the second refractive index layer.

17. The display device of claim 15, wherein the first refractive index layer comprises a plurality of first pore passages, the second refractive index layer comprises a plurality of second pore passages, and the third refractive index layer comprises a plurality of third pore passages, and
wherein some of the first color conversion particles are disposed in the plurality of first pore passages, and some of the second color conversion particles are disposed in the plurality of second pore passages.

18. The display device of claim 14, comprising:
a light-transmitting layer configured to transmit the first color light on the third refractive index layer.

19. The display device of claim 14, comprising:
a bank between the first refractive index layer, the second refractive index layer, and the third refractive index layer.

20. The display device of claim 1, wherein the color conversion layer has a thickness that is 1/10 or less of a thickness of the refractive index layer.
